(19) United States
(12) Patent Application Publication
(10) Pub. No.: US 2023/0178333 A1
(43) Pub. Date: Jun. 8, 2023

(54) ANALYSIS SYSTEM, ANALYSIS METHOD, COMPUTER PROGRAM PRODUCT AND SAMPLE HOLDER

(71) Applicant: Carl Zeiss Microscopy GmbH, Jena (DE)

(72) Inventor: Bruno Linn, Geisenfeld (DE)

(21) Appl. No.: 18/073,691

(22) Filed: Dec. 2, 2022

(30) Foreign Application Priority Data
Dec. 3, 2021 (DE) 102021131899.8

(51) Int. Cl. H01J 37/29; H01J 37/18; H01J 37/20; H01J 37/141

(52) U.S. Cl. CPC H01J 37/292; H01J 37/18; H01J 37/20; H01J 37/141; H01J 2237/2813; H01J 2237/2002

(57) ABSTRACT

An analysis system, an analysis method and a sample holder make it possible to analyse a battery via a particle beam system, for example to record images of the battery via the particle beam system, while the battery is arranged in a vacuum chamber of the particle beam system and is manipulated according to a multiplicity of different parameter value sets in the vacuum chamber. By way of example, the battery is kept at a predefined temperature, a predefined pressure is exerted on the battery, and the battery is electrically charged and discharged according to a loading scheme and at the same time images of the battery are recorded via the particle beam system.

### CROSS-REFERENCE TO RELATED APPLICATION

This application claims benefit under 35 U.S.C. § 119 to German Application No. 10 2021 131 899.8, filed Dec. 3, 2021. The contents of this application is hereby incorporated by reference in its entirety.

### FIELD

The present disclosure relates to an analysis system, an analysis method, a computer program product and a sample holder for manipulating and analysing an object, such as a battery.

### BACKGROUND

Batteries are stores for electrical energy. Rechargeable batteries are used in numerous technological fields. A constant aim in the further development of battery technologies is to increase the energy density and the lifetime of batteries.

One promising battery technology is the solid-state battery, in which both the electrodes and the electrolyte consist of a solid. In order that the battery technology of the solid-state battery can be developed further, it is desirable to understand the processes proceeding in the battery. However, in general, conventional analysis systems and analysis methods are not able to analyse processes in the battery at a microscopic level during its loading by charging or discharging.

### SUMMARY

The present disclosure seeks to provide improved possibilities for analysing batteries during their loading.

A first aspect of the disclosure relates to an analysis system. The analysis system comprises a particle beam microscope having a vacuum chamber and at least one detector for detecting interaction products of an interaction between a particle beam of charged particles, the particle beam being generated by the particle beam microscope, and a sample arranged in the vacuum chamber; and a sample manipulator for holding and manipulating the sample in the vacuum chamber. The sample manipulator is designed such that the particle beam can impinge on the sample held in the vacuum chamber by the sample manipulator. The sample manipulator comprises a loading device, a pressure adjusting device and a temperature adjusting device. The loading device is configured to electrically charge and/or electrically discharge the sample held in the vacuum chamber by the sample manipulator. The pressure adjusting device is configured to exert an adjustable mechanical pressure on the sample held in the vacuum chamber by the sample manipulator. The temperature adjusting device is configured to variably adjust a temperature of the sample held in the vacuum chamber by the sample manipulator.

The particle beam microscope is a scanning electron microscope or a scanning ion microscope, for example.

The sample is a battery, for example. A battery comprises electrodes and an electrolyte. A battery can be a solid-state battery, but also a battery of a different battery type. The electrodes and the electrolyte of a solid-state battery consist of solids. The battery can be a primary cell or secondary cell. A primary cell is a non-rechargeable battery. A secondary cell is a rechargeable battery.

The detector can be configured for example to detect particles of the particle beam generated by the particle beam microscope that are backscattered at the sample (for example backscattered electrons or ions) or secondary particles (for example secondary electrons or secondary ions) or radiation (for example x-ray beam).

The sample manipulator can be configured to bring the sample to a predetermined, variably adjustable state by the sample manipulator acting on the sample according to a parameter value set. The parameter value set can comprise parameter values for a plurality of different parameters of the sample.

One parameter of the sample that is manipulable by the sample manipulator is the loading of the sample by electrical charging and/or electrical discharging of the sample. During charging of the sample, a charging current (electric current) is supplied to the sample and taken up by the sample. In the case of secondary cells, the charging current brings about a chemical reaction in the sample, as a result of which electrical energy supplied by the charging current is permanently stored in the sample. The opposite process is performed during this charging of the sample. That means that electrical energy stored in the sample is released by the sample in the form of a discharge current (electric current) as a result of a chemical reaction. The sample manipulator is configured to manipulate the loading of the sample by charging and/or discharging of the sample by a loading device in accordance with a parameter value for adjusting the loading device. The loading device is configured to supply a charging current to the sample in accordance with the parameter value for adjusting the loading device or to draw a discharge current from the sample. Details of the loading device are described further below.

A further parameter of the sample that is manipulable by the sample manipulator is a mechanical pressure exerted on the sample. When pressure is exerted on the sample, a force acts on the sample. By way of example, the force can be exerted on the sample via the electrodes of the sample. The sample manipulator is configured to exert the pressure to be exerted on the sample via the pressure adjusting device in accordance with a parameter value for adjusting the pressure adjusting device. Details of the pressure adjusting device are described further below.

A further parameter of the sample that is manipulable by the sample manipulator is the temperature of the sample. The sample manipulator is configured to adjust the temperature of the sample via a temperature adjusting device according to a parameter value for adjusting the temperature adjusting device. The temperature adjusting device can be configured to cool the sample. Furthermore or alternatively, the temperature adjusting device can be configured to heat the sample. Details of the temperature adjusting device are described further below.

The sample manipulator can be designed such that the aforementioned manipulations of the sample can be performed (simultaneously) in the vacuum chamber of the particle beam microscope while a particle beam generated by the particle beam microscope is directed onto the sample and the interaction products generated as a result are detected.

Accordingly, the analysis system in accordance with the first aspect can make it possible to manipulate the sample and to analyse it during the manipulating or in the manipulated state via detecting interaction products. Accordingly, the analysis system in accordance with the first aspect can make it possible to perform a predefined test procedure with the parameters of loading, temperature and pressure on a battery and to observe the battery during the performance of the test procedure via the particle beam microscope.

In accordance with one embodiment, the loading device is configured to charge and/or to discharge the sample with a C-factor of at least 1/h, such as at least 3/h, for example at least 5/h, for example at least 10/h. The C-factor has the unit “per hour” [1/h]. The C-factor represents a current intensity of a charging or discharge current normalized to a rated capacity of the battery. When a battery having a rated capacity of 3/h Ah (ampere-hours) is charged, given a C-factor of 3, the charging current has a current intensity of 3/h×3 Ah=9 A (amperes). When this battery is discharged with a C-factor of 5/h, the discharge current has a current intensity of 5/h×3 Ah=15 A.

In accordance with one embodiment, the loading device comprises electrode terminals, which are electrically connectable to surface electrodes of the sample by contacting with the surface electrodes of the sample and which are electrically connectable to a driver device of the loading device. Surface electrodes denote electrodes arranged at the surface of the sample. In the case of a battery, the surface electrodes denote the electrodes of the battery which lie at the surface of the battery. In order to be able to charge and discharge the sample via the loading device, it is desirable to establish an electrical connection between the surface electrodes of the sample and the driver device of the loading device. For this purpose, the sample manipulator has the electrode terminals, which can be contacted with the surface electrodes of the sample. In addition, the electrode terminals are electrically connectable to the driver device of the loading device, for example via electrical lines. The electrode terminals are thus interfaces for the electrical connection of the surface electrodes of the sample to the driver device of the loading device.

In accordance with one embodiment, the driver device of the loading device comprises a current source and/or a current sink; and the loading device furthermore comprises electrical lines connecting the electrode terminals to the current source and/or the current sink. The current source serves for providing a charging current that is supplied to the sample via the electrical lines of the loading device and the electrode terminals. The current sink serves for consuming a discharge current that is drawn from the sample via the electrical lines of the loading device and the electrode terminals.

In accordance with one embodiment, the electrical lines of the loading device pass through a wall of the vacuum chamber of the particle beam microscope. That means that the electrical lines are led from the interior of the vacuum chamber to outside the vacuum chamber, even when the vacuum chamber is closed. In this embodiment, the driver device can be arranged outside the vacuum chamber of the particle beam microscope.

In accordance with one embodiment, the pressure adjusting device comprises a first plate for contacting with a first surface portion of the sample, a second plate for contacting with a second surface portion of the sample, and a drive configured to move the first plate and the second plate towards and away from one another. The pressure adjusting device exerts a pressure on the sample by virtue of the sample being arranged between the first plate and the second plate and, in this arrangement, the first plate and the second plate being moved towards one another by the drive. In this case, the first plate makes contact with the first surface portion of the sample (for example a surface electrode of the sample) and the second plate makes contact with the second surface portion of the sample (for example the other surface electrode of the sample). The pressure adjusting device can thereby hold the sample between the first plate and the second plate and exert a pressure on the sample. The drive can be an electrical, mechanical and/or hydraulic drive or a combination thereof.

In accordance with one embodiment, the drive is arranged in the vacuum chamber when the sample held by the sample manipulator is arranged in the vacuum chamber. That means that the drive is arranged in the vacuum chamber of the particle beam microscope during a measuring process using the particle beam microscope.

A driver device for operating the drive, for example an electrical circuit for providing an electric current to an electric motor (drive) or a hydraulic device for providing a hydraulic pressure to a hydraulic press (drive), can be connected to the drive via a supply line. The supply line can pass through a wall of the vacuum chamber of the particle beam microscope. In this case, the driver device can be arranged outside the vacuum chamber of the particle beam microscope.

In accordance with one embodiment, the pressure adjusting device is configured to exert a pressure of at least 10 MPa, such as at least 50 MPa, for example at least 100 MPa, on the sample.

In accordance with one embodiment, the temperature adjusting device is configured to heat and/or to cool the sample. The temperature adjusting device can act on the sample directly or indirectly, for example. The indirect adjusting of the temperature of the sample is effected by adjusting a temperature of a heat-conducting body that is in contact with the sample. By way of example, the temperature adjusting device can cool the temperature of the sample to temperatures of less than 0° C., such as less than −50° C. or less than −100° C. By way of example, the temperature adjusting device can heat the temperature of the sample to temperatures of above 50° C., such as above 100° C., for example above 150° C. The temperature adjusting device can comprise for example an electrothermal element (for example Peltier element) configured to variably adjust the temperature of the sample held in the vacuum chamber by the sample manipulator.

In accordance with one embodiment, the at least one detector comprises: a detector for detecting backscattered electrons and/or a detector for detecting secondary electrons and/or a detector for detecting backscattered ions and/or a detector for detecting secondary ions and/or a detector for detecting radiation. By way of example, the at least one detector can comprise an EDX detector for energy-dispersive x-ray spectroscopy. By way of example, the at least one detector can comprise an EBSD detector for detecting backscattered electrons. By way of example, the at least one detector can comprise a SIMS detector for secondary ion mass spectroscopy. Accordingly, numerous interaction products of different types can be detected.

In accordance with one embodiment, the analysis system comprises a controller configured to control the particle beam microscope and the sample manipulator. For example, the controller can control the loading device, the pressure adjusting device and the temperature adjusting device and also the components thereof.

The analysis systems described herein are suitable for performing the analysis methods described herein. For example, the controller of the analysis system can be configured to control the analysis system such that it performs the analysis methods described.

A second aspect of the disclosure relates to an analysis method for analysing a sample, such as a battery. The analysis method comprises: arranging a sample in a vacuum chamber of a particle beam microscope; and performing a measuring process for each parameter value set from a group of at least one parameter value set.

The measuring process comprises: manipulating the sample arranged in the vacuum chamber according to the respective parameter value set; directing a particle beam of charged particles, the particle beam being generated by the particle beam microscope, onto a surface of the sample arranged in the vacuum chamber, which sample has been or is being manipulated according to the respective parameter value set; and detecting interaction products of an interaction between the particle beam and the sample during the directing of the particle beam onto the surface of the sample. Accordingly, the sample in the vacuum chamber is manipulated in each measuring process. During the manipulating or after the manipulating, the sample is analysed by the particle beam being directed onto the sample and the interaction products produced in the process being detected.

Manipulating the sample arranged in the vacuum chamber according to the respective parameter value set can comprise: performing a loading process according to which the sample arranged in the vacuum chamber is electrically charged and/or electrically discharged, exerting a mechanical pressure on the sample arranged in the vacuum chamber, and adjusting a temperature of the sample arranged in the vacuum chamber.

The analysis method can be performed via the analysis systems described herein. For example, manipulating the sample in the vacuum chamber can be performed via the sample manipulator.

In accordance with the analysis method, the sample can be manipulated in the vacuum chamber of the particle beam microscope or the sample can be in a state corresponding to the manipulation while a particle beam generated by the particle beam microscope is directed onto the sample and the interaction products produced as a result are detected. Accordingly, the analysis method in accordance with the second aspect can make it possible to manipulate the sample and to analyse it during the manipulating or in the manipulated state via detecting interaction products. Accordingly, the analysis method in accordance with the second aspect can make it possible to perform a predefined test procedure with the parameters of loading, temperature and pressure on a battery and to observe the battery during the performance of the test procedure via the particle beam microscope.

In accordance with one embodiment, the at least one parameter value set comprises a parameter value for each manipulated parameter of the sample. By way of example, the at least one parameter value set comprises a parameter value for the loading process, a parameter value for the pressure, and a parameter value for the temperature of the sample. The parameter value for the loading process specifies for example a current intensity or a C-factor of a charging current or of a discharge current. Furthermore or alternatively, the parameter value for the loading process can specify a number of charging and/or discharging cycles of the charging and/or discharging of the sample. Accordingly, the parameter value for the loading process itself can comprise a multiplicity of parameter values which specify parameters of the loading process.

The parameter value for the pressure specifies for example the mechanical pressure which is to be exerted on the sample. Furthermore or alternatively, the parameter value for the pressure can specify a parameter value for controlling the drive which indirectly specifies the mechanical pressure to be exerted on the sample.

The parameter value for the temperature of the sample specifies for example a target temperature of open-loop temperature control or closed-temperature control.

In accordance with one embodiment, manipulating the sample arranged in the vacuum chamber according to the respective parameter value set comprises adjusting a sample manipulator according to the respective parameter value set and manipulating the sample arranged in the vacuum chamber via the adjusted sample manipulator. Accordingly, manipulating the sample in the vacuum chamber is performed by a sample manipulator, for example by the sample manipulator of the analysis systems described herein. In this case, the sample manipulator is adjusted according to the parameter value set. The sample manipulator then manipulates the sample in the vacuum chamber in accordance with this adjustment.

In accordance with one embodiment, the group comprises a multiplicity of different parameter value sets. The parameter value sets all relate to the same parameters and differ from one another by way of different parameter values assigned to the parameters. By way of example, the parameter value sets relate to the parameters of loading, pressure and temperature. Each parameter value set comprises a respective parameter value for each parameter. Two parameter value sets are different if the parameter values relating to a same one of the parameters differ from one another. The measuring process is performed successively for all parameter value sets of the group. Accordingly, the sample can be successively manipulated to different states, and during each manipulating, or while the respective state of the sample is produced, the sample can be analysed by detection of the interaction products respectively produced. In this way, a battery can successively undergo a multiplicity of charging and discharging cycles and in the meantime the sample is repeatedly analysed by detection of the interaction products.

In accordance with one embodiment, the sample remains in the vacuum chamber between the measuring processes. That means that the sample is not removed from the vacuum chamber during and between a multiplicity of measuring processes. A feature of the analysis system and the analysis method is that the sample can be subjected to a series of measurements involving a multiplicity of different sample states (as a result of the manipulating), without the sample having to be transferred to some other apparatus. This enables simple handling of the sample and a shorter duration for performing the multiplicity of measuring processes and also the maintenance of constant ambient conditions.

In accordance with one embodiment, performing the loading process comprises charging and/or discharging the sample with a C-factor of at least 1/h, such as at least 3/h, for example at least 5/h, for example at least 10/h.

In accordance with one embodiment, the mechanical pressure on the sample is at least 10 MPa, such as at least 50 MPa, for example at least 100 MPa.

In accordance with one embodiment, adjusting the temperature of the sample arranged in the vacuum chamber comprises heating and/or cooling the sample.

In accordance with one embodiment, the measuring process furthermore comprises recording at least one image of the sample on the basis of the detected interaction products. By way of example, the image is recorded by the particle beam being scanned over the surface of the sample and the interaction products being detected in the process.

In accordance with one embodiment, the measuring process furthermore comprises exposing the surface of the sample by removing a part of the sample from the sample. By way of example, removing a part of the sample can be effected by etching induced by the particle beam. Furthermore or alternatively, removing a part of the sample can be effected via a further particle beam (for example ion beam) that is different from the particle beam. Furthermore or alternatively, removing a part of the sample can be effected via laser ablation. For this purpose, the analysis system can comprise a further particle beam column and/or a laser besides the particle beam microscope. The further particle beam column and/or the laser can have the same working region as the particle beam microscope. As a result, removing a part of the sample can be performed without having to move the sample. Alternatively, the further particle beam column and/or the laser can have a working region that is spaced apart from the working region of the particle beam microscope. The working regions can be connected to one another by a lock, such that the sample can be transferred directly between the working regions.

In accordance with one embodiment, the interaction products comprise backscattered electrons, secondary electrons, backscattered ions, secondary ions and/or radiation.

A third aspect of the disclosure relates to a computer program product containing computer-readable instructions which cause a controller of an analysis system, for example of one of the analysis systems described herein, to carry out one of the analysis methods described herein. A computer program product is a data carrier (CD, DVD, floppy disk, etc.), for example. Alternatively, the computer program product can be realized in the form of stored data.

A fourth aspect of the disclosure relates to a sample holder for holding and manipulating a sample, for example a battery, in a vacuum chamber of a particle beam microscope. The sample holder comprises electrode terminals, which are electrically connectable to surface electrodes of the sample by contacting with the surface electrodes of the sample and which are electrically connectable to electrical lines of a loading device. The sample holder furthermore comprises a first plate for contacting with a first surface portion of the sample, a second plate for contacting with a second surface portion of the sample, and a drive configured to move the first plate and the second plate towards and away from one another, such that an adjustable mechanical pressure is exertable on the sample via the first plate and the second plate. The sample holder furthermore comprises an electrothermal element configured to variably adjust the temperature of the sample held in the vacuum chamber by the sample manipulator.

The sample holder can be arranged completely in the vacuum chamber of the particle beam microscope. In contrast to the sample manipulator, the sample holder comprises only those component parts of the sample manipulator which are arranged in the vacuum chamber of the particle beam microscope during the performance of measuring processes.

In accordance with one embodiment, the sample holder comprises a securing interface for securing the sample holder to a positioning stage that is arrangeable in the vacuum chamber. Furthermore or alternatively, the sample holder can comprise a positioning stage. A positioning stage comprises a plurality of controllable actuators that can move the sample holder mounted on the positioning stage. The positioning stage can provide one or more translational degrees of freedom of movement and/or one or more rotational degrees of freedom of movement.

### BRIEF DESCRIPTION OF THE DRAWINGS

Embodiments of the disclosure are explained in greater detail below with reference to figures, in which:

FIG. 1 shows a schematic illustration of an analysis system in accordance with the first aspect of the disclosure;

FIG. 2 shows a schematic illustration of a sample manipulator of the analysis system;

FIG. 3 shows a flow diagram of an analysis method in accordance with the second aspect of the disclosure; and

FIG. 4 shows a flow diagram of exemplary manipulating of a sample in accordance with the analysis method.

### DETAILED DESCRIPTION

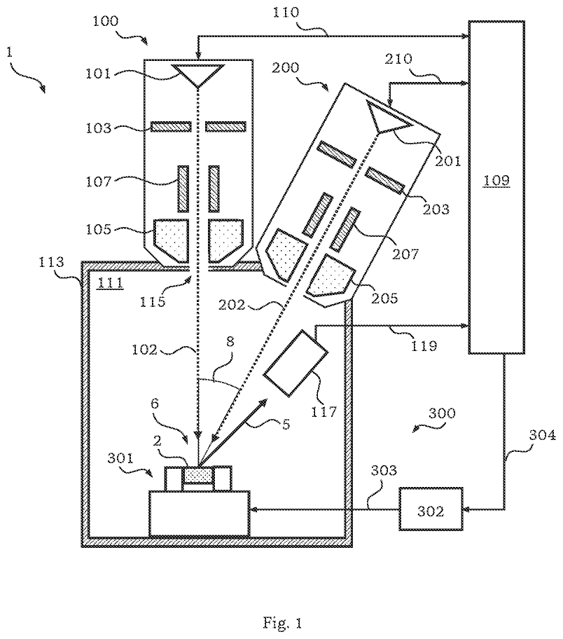

FIG. 1 shows a schematic illustration of an exemplary analysis system 1 for analysing a sample 2. The analysis system 1 comprises a particle beam microscope 100. The particle beam microscope 100 comprises a particle source 101 configured to generate a particle beam 102 of charged particles. The particle source 101 can be brought to a high temperature with an electric heating current and an electrical potential can also be applied to it. The particle beam 102 is formed for example from electrons or ions.

The particle beam microscope 100 furthermore comprises an acceleration electrode 103, to which an electrical potential can be applied in order to accelerate the particles emitted by the particle source 101 to a predetermined kinetic energy. The kinetic energy of the particles is therefore (approximately) proportional to the potential difference between the electrical potentials of the particle source 101 and the acceleration electrode 103.

The particle beam microscope 100 furthermore comprises an objective lens 105 suitable for focusing the particle beam 102 onto the sample 2. For this purpose, the objective lens 105 can generate a magnetic field and/or an electric field.

The particle beam microscope 100 furthermore comprises a deflector system 107 suitable for deflecting the particle beam 102, with the result that the particle beam 102 can be directed onto different locations on a surface of the Sample 2. The deflector system 107 can be suitable for deflecting the particle beam 102 along two mutually perpendicularly oriented directions, which are each in turn oriented perpendicularly to an optical axis of the objective lens 105.

The particle beam microscope 100 further comprises a controller 109 configured to control the particle beam microscope 100. For this purpose, the controller 109 is connected to the particle beam microscope 100 via a communication and supply connection 110. The communication and supply connection 110 can comprise a multiplicity of connections which connect the individual components to be controlled of the particle beam microscope 100 to the controller 109. Only one representative connection is shown, in order to simplify the drawing. The controller 109 is configured to control the particle source 101 (for example the heating current thereof and the electrical potential applied thereto), the electrical potential applied to the acceleration electrode 103, the deflector system 107 and the objective lens 105.

The particle beam microscope 100 further comprises a vacuum chamber 111. The vacuum chamber 111 has a chamber wall 113, which spatially delimits the vacuum chamber 111. A vacuum can be generated in the vacuum chamber 111, for example by a vacuum pump connected to the vacuum chamber 111 via a line. The vacuum chamber 111 is connected to the particle beam microscope 100 and has an opening 115, through which the particle beam 102 can enter the vacuum chamber 111.

The particle beam microscope 100 furthermore comprises a detector 117 suitable for detecting interaction products 5 generated by interaction of the particle beam 102 with the sample 2. The interaction products 5 can be for example backscattered electrons, secondary electrons, backscattered ions, secondary ions or generated radiation (photons, x-ray radiation). In the example shown, the detector 117 is arranged in the vacuum chamber 111. In some cases, however, the detector 117 can also be arranged outside the vacuum chamber 111. In further cases, the detector 117 can be arranged in the particle beam microscope 100. The detector 117 is suitable for outputting a detection signal depending on the detected interaction products. By way of example, the detection signal represents a detection rate of the detecting of the interaction products 5. The controller 109 can receive the detection signal from the detector 117 via a communication connection 119 and can process it and display it on a display device, for example. An image of the sample 2 can be recorded by way of the controller 109 by directing the particle beam 102 onto a multiplicity of locations of the sample 2 and detecting the interaction products 5 generated in this way.

The analysis system 1 furthermore comprises a particle beam column 200 for processing the sample 2 with a particle beam 202 of charged particles. The particle beam column 200 is an ion beam column, for example. The particle beam column 200 is configured similarly to the particle beam microscope 100 and comprises a particle source 201, an acceleration electrode 203, an objective lens 205 and a deflector system 207. The particle beam microscope 100 and the particle beam column 200 have a common working region 6. The particle beam column 200 is likewise controlled by the controller 109.

The sample 2 is arranged in the common working region 6. Therefore, both the particle beam microscope 100 and the particle beam column 200 simultaneously analyse and process the sample 2 without having to move the sample 2. An (acute) angle 8 between an optical axis of the objective lens 105 and an optical axis of the objective lens 205 usually has a value in the range of 50° to 60°, in special cases of 90°.

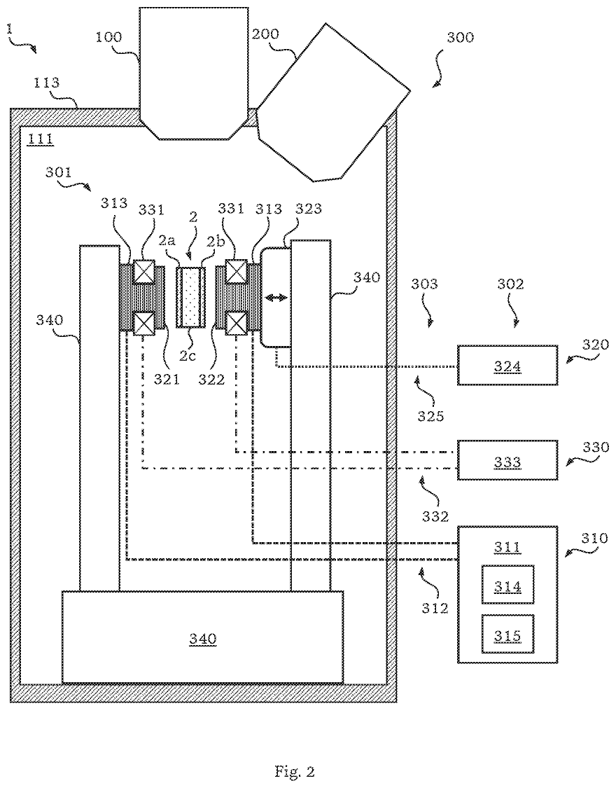

The analysis system 1 furthermore comprises a sample manipulator 300 for holding and manipulating the sample in the vacuum chamber 111. FIG. 2 shows a schematic illustration of the sample manipulator 300 of the analysis system 1, wherein the sample 2 is a battery comprising, inter alia, two electrodes 2a, 2b (anode and cathode) and an electrolyte 2c. The electrodes 2a and 2b lie at the surface of the sample 2 and are accordingly surface electrodes.

The sample manipulator 300 comprises a sample holder 301 arranged within the vacuum chamber 111, a controller part 302 arranged outside the vacuum chamber 111, and communication and supply connections 303 connecting the sample holder 301 to the controller part 302. The controller part 302 is connected to the controller 109 via a communication connection 304. The controller 109 controls the sample manipulator 300 by controlling the controller part 302 of the sample manipulator 300. The controller part 302 can be realized partly or completely by the controller 109.

The sample manipulator 300 functionally comprises a loading device 310, a pressure adjusting device 320 and a temperature adjusting device 330.

The loading device 310 is configured to electrically charge and/or electrically discharge the sample 2 held in the vacuum chamber 111 by the sample manipulator 300. For this purpose, the loading device 310 comprises for example a driver device 311 (part of the controller part 302), which is electrically connected to electrode terminals 313 of the sample holder 301 via electrical lines 312 (part of the communication and supply connections 303). The electrical lines 312 are schematically represented by dashed lines. The driver device 311 comprises a current source 314 and/or a current sink 315, for example. The electrical lines 312 pass through the chamber wall 113 of the vacuum chamber 111. The electrode terminals 313 of the sample holder 301 can be electrically connected to the electrodes 2a and 2b of the sample 2 by the electrode terminals 213 being contacted with the electrodes 2a and 2b of the Sample 2. This can be performed via the pressure adjusting device 320 described below.

The pressure adjusting device 320 is configured to exert an adjustable mechanical pressure on the sample 2 held in the vacuum chamber 111 by the sample manipulator 300. For this purpose, the pressure adjusting device 320 comprises for example a first plate 321, a second plate 322, a drive 323, a driver device 324 (part of the controller part 302) and a supply connection 325 (part of the communication and supply connections 303). The drive 323 is configured to move the first plate 321 and the second plate 322 towards and away from one another, which is illustrated by a double-headed arrow in FIG. 2. The driver device 324 controls the drive 323 via the supply connection 325. The supply connection 325 is schematically represented by a dotted line. The supply connection 325 passes through the chamber wall 113 of the vacuum chamber 111.

The pressure adjusting device 320 serves for holding the sample 2, which is achieved by the drive 323 moving the first plate 321 and the second plate 322 towards one another, while the sample 2 is arranged between the first plate 321 and the second plate 322 (for example via a gripping device (not shown) of the particle beam microscope 100), until the sample 2 is clamped in between the first plate 321 and the second plate 322. In this case, a first surface portion (in FIG. 2: electrode 2a) of the sample 2 makes contact with the first plate 321 and a second surface portion (in FIG. 2: electrode 2b) of the sample 2 makes contact with the second plate 322. Consequently, via the drive, the mechanical pressure exerted on the sample 2 by the first plate 321 and the second plate 322 can be increased or reduced, depending on control by the driver device 324. In the example shown in FIG. 2, the first plate 321 provides one of the electrode terminals 313, and the second plate 322 likewise provides one of the electrode terminals 313.

The temperature adjusting device 330 is configured to variably adjust a temperature of the sample 2 held in the vacuum chamber 111 by the sample manipulator 300. For this purpose, the temperature adjusting device 330 comprises for example an electrothermal element 331 configured to heat and/or to cool the sample 2. The electrothermal element 331 is supplied with an adjustable electric current by a driver device 333 (part of the controller part 302) via a supply connection 332 (part of the communication and supply connections 303). The supply connection 332 is schematically represented by a dash-dotted line. The supply connection 332 passes through the chamber wall 113 of the vacuum chamber 111.

In the example shown in FIG. 2, the sample 2 is not directly cooled or heated by the temperature adjusting device 330, but rather indirectly via a heat-conducting body. That means that the electrothermal element 331 directly heats or cools the heat-conducting body (in FIG. 2: the first plate 321 and the second plate 322), and that the heat-conducting body performs heat exchange with the sample 2.

The sample manipulator 300 furthermore comprises a positioning stage 340. The positioning stage 340 can be a conventional positioning stage which provides translational and/or rotational degrees of freedom of movement for moving the sample 2 or the sample holder 301 relative to the vacuum chamber 111. By way of example, the sample holder 301 can be designed as an attachment on a conventional positioning stage 340. In this case, the sample holder 301 has a securing interface for securing the sample holder 301 to the positioning stage 340. Alternatively, the positioning stage 340 can be integrated in the sample holder 301.

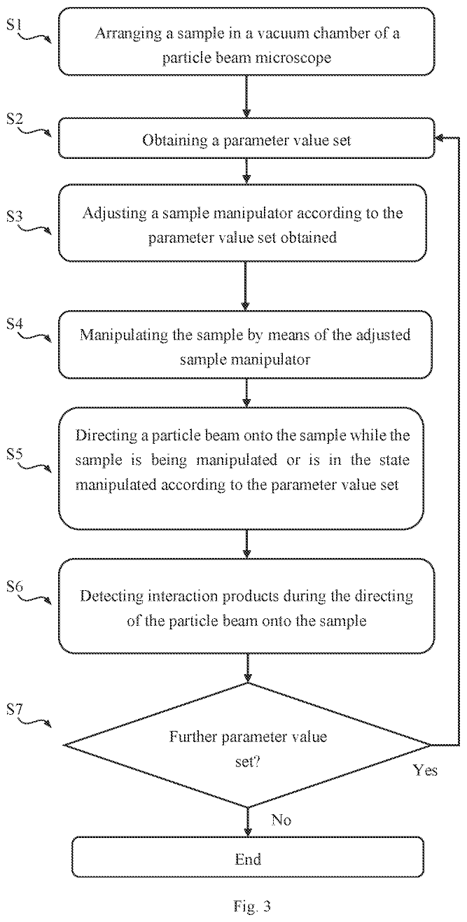

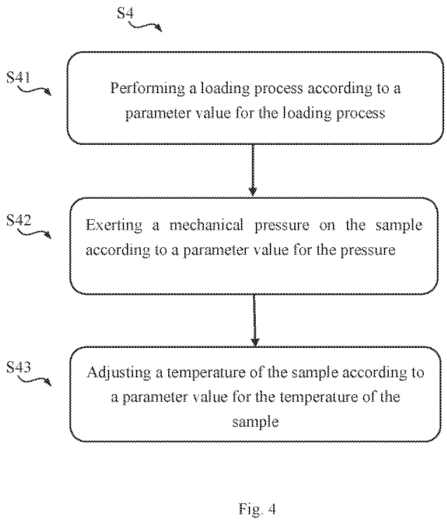

An analysis method in accordance with the second aspect of the disclosure is described below with reference to FIGS. 3 and 4. As an example, the analysis method is performed by the analysis system 1.

In a first step S1, the sample 2 is arranged in the vacuum chamber 111 of the particle beam microscope 100.

Afterward, a measuring process is performed in steps S2 to S6. The measuring process is performed according to a parameter value set. The measuring process can be carried out for each parameter value set of a group of different parameter value sets by the measuring process being performed in succession over time with in each case one parameter value set of the group. The group comprises at least one parameter value set.

Each parameter value set of the group comprises a parameter value for a loading process, a parameter value for a mechanical pressure to be exerted on the sample, and a parameter value for a temperature to be adjusted of the sample. Different parameter value sets differ in at least one of these parameter values. By way of example, different parameter value sets each have the same parameter value for the pressure and the same parameter value for the temperature of the sample, but have different parameter values for the loading process. By way of example, a parameter value for the loading process of a first parameter value set specifies that the sample is to be charged once in total and is to be discharged once in total, whereas a parameter value for the loading process of a second parameter value set specifies that the sample is to be charged twice in total and is to be discharged twice in total.

Step S2 involves obtaining a parameter value set for the next measuring process. The parameter value set for the next measuring process can for example be defined by a user and/or be read from a memory in which predefined parameter value sets are stored.

In steps S3 and S4, the sample is manipulated according to the parameter value set obtained in step S2. In the present case, the method is performed by the analysis system 1, such that manipulating the sample 2 is performed by the sample manipulator 300. For this purpose, in step S3, the sample manipulator 300 is adjusted according to the parameter value set obtained. This comprises for example adjusting the controller part 302 in accordance with the obtained parameter value set via the controller 109. In step S4, the sample manipulator 300 manipulates the sample 2 in accordance with the adjustment effected in step S3.

In steps S5 and S6, the sample 2 is analysed while the sample 2 is being or has been manipulated. In step S5, the particle beam microscope 100 directs the particle beam 102 onto a surface of the sample 2. The interaction products 5 generated as a result are detected in step S6.

Step S7 involves checking whether the measuring process is intended to be performed with a further parameter value set. If it is ascertained in step S7 that the measuring process is intended to be performed with a further parameter value set (Yes in step S7), the method is repeated starting from step S2. If it is ascertained in step S7 that the measuring process is not intended to be performed with a further parameter value set (No in step S7), the method ends

Steps S2 to S6 do not have to be performed successively over time. By way of example, steps S5 and S6 are performed at least partly simultaneously.

As is illustrated in FIG. 4, step S4 can comprise three steps S41 to S43. Steps S41 to S43 do not have to be performed successively over time. By way of example, steps S41 to S43 are performed at least partly simultaneously.

Step S41 involves performing a loading process according to which the sample 2 is electrically charged and/or electrically discharged. By way of example, the loading process is performed via the loading device 310 according to the parameter value for the loading process.

In step S42, a mechanical pressure is exerted on the sample 2. By way of example, the pressure is exerted via the pressure adjusting device 320 according to the parameter value for the pressure.

In step S43, the temperature of the sample 2 is adjusted. By way of example, the temperature of the sample 2 is adjusted via the temperature adjusting device 330 according to the parameter value for the temperature.

Between the measuring processes, the sample 2 is not taken out of the vacuum chamber 111. Between the measuring processes, the sample 2 can be processed via the particle beam column 200. For example, the particle beam column 200 can be used to ablate a part of the sample 2 from the sample 2 in order to make the effect of the manipulations within the sample 2 accessible to the particle beam microscope 100. After the end of the method, the sample 2 can be taken out of the vacuum chamber 111.

What is claimed is:

1. A system, comprising:
a particle beam microscope comprising a vacuum chamber and a detector configured to detect interaction products of an interaction between a sample in the vacuum chamber and a particle beam of charged particles generated by the particle beam microscope; and
a sample manipulator configured to hold and manipulate the sample in the vacuum chamber,
wherein:
the sample manipulator is configured so that the particle beam is impingeable on the sample when held in the vacuum chamber by the sample manipulator; and
the sample manipulator comprises:
a loading device configured to electrically charge and/or electrically discharge the sample when held in the vacuum chamber by the sample manipulator;
a pressure adjusting device configured to exert an adjustable mechanical pressure on the sample when held in the vacuum chamber by the sample manipulator; and
a temperature adjusting device configured to variably adjust a temperature of the sample when held in the vacuum chamber by the sample manipulator.

2. The system of claim 1, wherein the loading device is configured to charge and/or to discharge the sample with a C-factor of at least 1/h.

3. The system of claim 1, wherein the loading device comprises electrode terminals electrically connectable to surface electrodes of the sample via contact with the surface electrodes of the sample, the electrode terminals being electrically connectable to a driver device of the loading device.

4. The system of claim 3, wherein the driver device comprises a current source and/or a current sink, and the loading device further comprises electrical lines connecting the electrodes terminals to the current source and/or the current sink.

5. The system of claim 4, wherein the electrical lines of the loading device pass through a chamber wall of the vacuum chamber.

6. The system of claim 1, wherein the pressure adjusting device comprises:
a first plate configured to contact a first surface portion of the sample;
a second plate configured to contact a second surface portion of the sample; and
a drive configured to move the first plate and the second plate towards and away from one another.

7. The system of claim 6, wherein the drive is in the vacuum chamber when the sample is held by the sample manipulator, and the sample is in the vacuum chamber.

8. The system of claim 1, wherein the pressure adjusting device is configured to exert a pressure of at least 10 MPa.

9. The system of claim 1, wherein the temperature adjusting device is configured to heat and/or to cool the sample.

10. The system of claim 1, wherein the temperature adjusting device is configured to indirectly change the temperature of the sample by adjusting a temperature of a heat-conducting body that is in contact with the sample.

11. The system of claim 1, wherein the temperature adjusting device comprises an electrothermal element configured to variably adjust the temperature of the sample when held in the vacuum chamber by the sample manipulator.

12. The system of claim 1, wherein the detector comprises:
a detector configured to detect at least one member selected from the group consisting of backscattered electrons secondary electrons; and/or
a detector configured to detect at least one member selected from the group consisting of backscattered ions, secondary ions and radiation.

13. The system of claim 1, further comprising a controller configured to control the particle beam microscope and the sample manipulator.

14. A method, comprising:
arranging a sample in a vacuum chamber of a particle beam microscope; and
performing a measuring process for each parameter value set from a group of at least one parameter value set,
wherein the measuring process comprises:
manipulating the sample in the vacuum chamber according to the respective parameter value set;
directing a particle beam of charged particles, the particle beam being generated by the particle beam microscope, onto a surface of the sample in the vacuum chamber, the sample having been or being manipulated according to the respective parameter value set; and
detecting interaction products of an interaction between the particle beam and the sample during the directing of the particle beam onto the surface of the sample,
wherein manipulating the sample in the vacuum chamber according to the respective parameter value set comprises:
performing a loading process according to which the sample in the vacuum chamber is electrically charged and/or electrically discharged;
exerting a mechanical pressure on the sample in the vacuum chamber; and
adjusting a temperature of the sample in the vacuum chamber.

15. The method of claim 14, wherein the at least one parameter value set comprises:
a parameter value for the loading process;
a parameter value for the pressure; and
a parameter value for the temperature of the sample.

16. The method of claim 14, wherein manipulating the sample arranged in the vacuum chamber according to the respective parameter value set comprises:
adjusting a sample manipulator according to the respective parameter value set; and
manipulating the sample in the vacuum chamber via the adjusted sample manipulator.

17. The method of claim 14, wherein the group comprises a multiplicity of different parameter value sets.

18. One or more machine-readable hardware storage devices comprising instructions that are executable by one or more processing devices to perform operations comprising the method of claim 14.

19. A system comprising:
one or more processing devices; and
one or more machine-readable hardware storage devices comprising instructions that are executable by the one or more processing devices to perform operations comprising the method of claim 14.

20. A holder configured to hold and manipulate a sample in a vacuum chamber of a particle beam microscope, the holder comprising:
electrode terminals that are electrically connectable to surface electrodes of the sample by contacting with the surface electrodes of the sample, the electrode terminals being electrically connectable to electrical lines of a loading device;
a first plate configured to contact a first surface portion of the sample;
a second plate configured to contact a second surface portion of the sample;
a drive configured to move the first and second plates relative to one another so that an adjustable mechanical pressure is exertable on the sample via the first and second plates; and
an electrothermal element configured to variably adjust a temperature of the sample when held in the vacuum chamber by the sample manipulator.
